(19) United States
(12) Patent Application Publication
(10) Pub. No.: US 2026/0162922 A1
(43) Pub. Date: Jun. 11, 2026

(54) OBSERVATION UNIT, TRAVELING WAVE TUBE UNIT, MICROWAVE TUBE UNIT, AND OBSERVATION METHOD

(71) Applicant: NEC Network and Sensor Systems, Ltd., Tokyo (JP)

(72) Inventors: Koji YAMAMOTO, Tokyo (JP); Takashi Nakano, Tokyo (JP)

(73) Assignee: NEC Network and Sensor Systems, Ltd., Tokyo (JP)

(21) Appl. No.: 19/366,981

(22) Filed: Oct. 23, 2025

(30) Foreign Application Priority Data
Dec. 5, 2024 (JP) 2024-212238

(51) Int. Cl. H01J 37/14; H01J 25/42

(52) U.S. Cl. CPC H01J 37/14; H01J 25/42

(57) ABSTRACT

An observation unit including: a housing having a vacuum inside; a pedestal accommodated in the housing and fixed to the housing; and an observation device accommodated in the housing and supported by the pedestal, wherein the pedestal includes a first magnet, and the observation device includes a second magnet installed so as to repel the first magnet, and is supported in a state of being separated from the pedestal.

This application is based upon and claims the benefit of priority from Japanese Patent Application No. 2024-212238, filed on Dec. 5, 2024, the disclosure of which is incorporated herein in its entirety by reference.

### TECHNICAL FIELD

The present disclosure relates to an observation unit, a traveling wave tube unit, a microwave tube unit, and an observation method.

### BACKGROUND ART

For example, JP 2023-154892 A discloses a measurement-device-accommodating heat-insulating container that suppresses heat transfer between the inside and outside of the container. The measurement-device-accommodating heat-insulating container disclosed in JP 2023-154892 A includes a vacuum heat-insulating container portion having a cylindrical shape with a closed bottom. A measurement device is placed inside the vacuum heat-insulating container portion.

### SUMMARY

An observation unit according to an aspect of the present disclosure includes: a housing having a vacuum inside; a pedestal accommodated in the housing and fixed to the housing; and an observation device accommodated in the housing and supported by the pedestal, wherein the pedestal includes a first magnet, and the observation device includes a second magnet installed so as to repel the first magnet, and is supported in a state of being separated from the pedestal.

A traveling wave tube unit according to an aspect of the present disclosure includes: a traveling wave tube; and the above-described observation unit for observing the traveling wave tube.

A microwave tube unit according to an aspect of the present disclosure includes: a microwave tube; and the above-described observation unit for observing the microwave tube.

An observation method according to an aspect of the present disclosure includes: accommodating a pedestal and an observation device inside a housing having a vacuum inside; supporting the observation device in a state of being separated from the pedestal by using a repulsive force between a first magnet included in the pedestal fixed to the housing and a second magnet included in the observation device; and performing observation using the observation device in a state of being separated from the pedestal.

### BRIEF DESCRIPTION OF THE DRAWINGS

FIG. 1 is a schematic diagram of a first observation unit of the present disclosure;

FIG. 2 is a schematic diagram of a traveling wave tube unit of the present disclosure;

FIG. 3 is a schematic diagram of a microwave tube unit of the present disclosure; and

FIG. 4 is a schematic diagram of a second observation unit of the present disclosure.

### EXAMPLE EMBODIMENT

Hereinafter, example embodiments of an observation unit, a traveling wave tube unit, a microwave tube unit, and an observation method according to the present disclosure will be described with reference to the drawings.

### First Example Embodiment

An observation unit 1 of the present example embodiment is a unit that performs observation in a high-temperature environment of, for example, about 1000° C. This observation includes, for example, receiving visible light and converting it into an electrical signal of a predetermined standard, and receiving radio waves and converting them into electrical signals of a predetermined standard. This observation unit 1 of the present example embodiment includes a housing 2, a pedestal 3, an observation device 4, an observation device antenna 5 (first antenna), and a housing antenna 6 (second antenna).

The housing 2 is formed of, for example, a heat-insulating material, and is designed to insulate heat and thereby suppress the transfer of external heat to the inside. The housing 2 is formed in a box shape and has a vacuum inside it. Note that the term vacuum here does not mean that no gas is present, but means that the degree of vacuum is higher than that at atmospheric pressure. That is, the inside of the housing 2 is depressurized. For example, the inside of the housing 2 can be brought into a vacuum state by using, for example, a vacuum exhaust device (not illustrated). For example, the inside of the housing 2 can be brought into a vacuum state by being connected with a vacuum space (not illustrated).

The housing 2 has an observation window 2a (signal passing portion) in a portion thereof. The observation window 2a is a part that allows observation target signals to pass from the outside of the housing 2 to the inside of the housing 2. In the present example embodiment, the observation device 4 is an imaging device. Therefore, the observation device 4 receives light as an observation target signal and converts the light, that is, the observation target signal into an electrical signal. Therefore, in the present example embodiment, the observation window 2a enables light to pass from the outside of the housing 2 to the inside of the housing 2 as an observation target signal.

For example, in a case where the observation device 4 is an imaging device that converts visible light into an electrical signal, the observation window 2a is formed of a material through which visible light can pass. As another example, in a case where the observation device 4 is an imaging device that converts infrared light into an electrical signal, the observation window 2a is formed of a material through which infrared light can pass. As another example, in a case where the observation device 4 is an imaging device that converts ultraviolet light into an electrical signal, the observation window 2a is formed of a material through which ultraviolet light can pass.

In addition, when the observation device 4 is a radio wave observer using a radio wave as an observation target signal, an antenna that receives the observation target signal outside the housing 2 and emits the observation target signal into the housing 2 may be provided as a signal passing portion instead of the observation window 2a. Such an observation window 2a (signal passing portion) is preferably arranged at a position where external light (the observation target signal) easily reaches the observation device 4.

Note that, depending on the type of the observation target signal, the observation target signal may be able to pass through the entire housing 2. When the observation target signal can pass through the entire housing 2, the signal passing portion may not be provided in a portion of the housing 2.

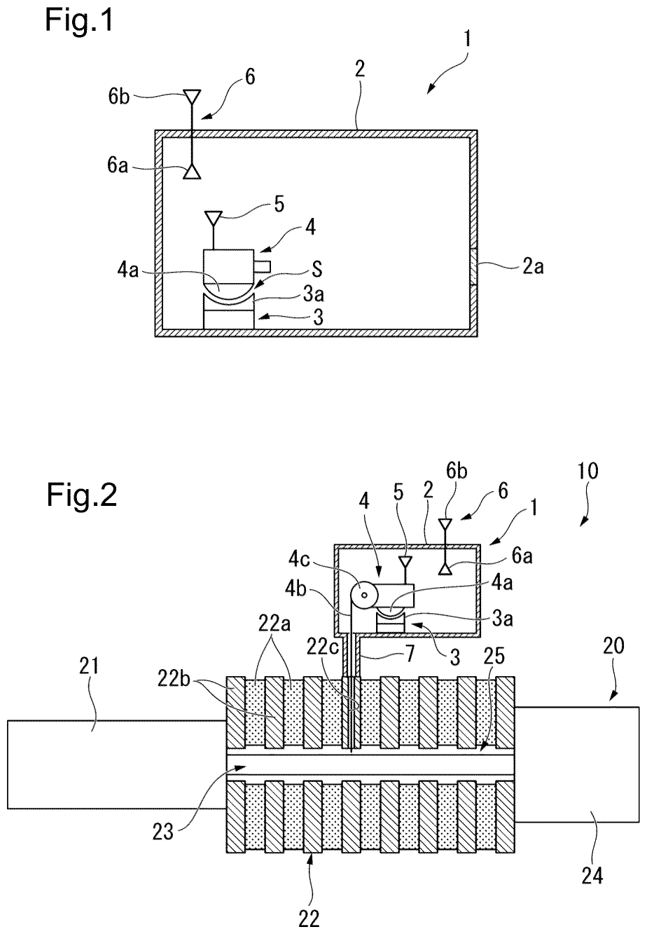

The pedestal 3 is accommodated in the housing 2. As illustrated in FIG. 1, the pedestal 3 is fixed to the bottom of the housing 2. The pedestal 3 includes a pedestal magnet 3a (first magnet). The pedestal magnet 3a and an observation device magnet 4a described later are arranged so that the same poles face each other. As illustrated in FIG. 1, the pedestal magnet 3a may be formed in a recessed shape in which the central portion is lower than the periphery. The observation device magnet 4a is arranged on the pedestal magnet 3a having such a recessed shape.

Such a pedestal 3 supports the observation device 4 from below by the magnetic force generated by the pedestal magnet 3a. That is, a gap S is provided between the pedestal 3 and the observation device 4, and the observation device 4 is supported in a non-contact state with respect to the pedestal 3. It is only necessary to provide one or more pedestals 3. In other words, a plurality of pedestals 3 may be provided.

The observation device 4 is accommodated in the housing 2. The observation device 4 is a device that observes a state outside the housing 2. In the present example embodiment, the observation device 4 is an imaging device. However, the observation device 4 is not limited to an imaging device, and may be any device that receives an observation target signal and converts it into an electrical signal.

As illustrated in FIG. 1, the observation device 4 includes the observation device magnet 4a (second magnet). The observation device magnet 4a and the pedestal magnet 3a are arranged so that the same poles face each other. That is, when the surface of the pedestal magnet 3a facing the observation device magnet 4a is the N pole, the surface of the observation device magnet 4a facing the pedestal magnet 3a is also the N pole. When the surface of the pedestal magnet 3a facing the observation device magnet 4a is the S pole, the surface of the observation device magnet 4a facing the pedestal magnet 3a is also the S pole. Therefore, the observation device magnet 4a is disposed so as to repel the pedestal magnet 3a. The observation device 4 is supported in a floating state by a repulsive force generated between the pedestal magnet 3a and the observation device magnet 4a. That is, the observation device 4 is supported in a state of being separated from the pedestal 3.

As described above, the inside of the housing 2 is vacuum. Therefore, the observation device 4 is surrounded by a vacuum space and is thermally disconnected from the housing 2. The observation device magnet 4a may have an outer wall surface along the inner wall surface of the pedestal magnet 3a formed in a recessed shape. In such a case, the observation device magnet 4a has a protruded shape in which the central portion bulges toward the pedestal 3. When a plurality of pedestals 3 are provided, the observation device 4 may include a plurality of observation device magnets 4a according to the number of pedestals 3.

In addition, the observation device 4 may include a storage unit that stores an observation result. The observation device 4 having such a storage unit can store observation data. In addition, the observation device 4 may have a battery. The observation device 4 including such a battery can be driven in a state where power supply is interrupted from the outside. In a case where the observation device 4 includes a storage unit and a battery, the observation unit 1 may not include the observation device antenna 5 and the housing antenna 6.

The observation device antenna 5 is an antenna installed in the observation device 4. The observation device antenna 5 enables the observation device 4 and the housing antenna 6 to be wirelessly connected. The observation device antenna 5 wirelessly transmits, for example, observation data observed by the observation device 4 via the housing antenna 6. In addition, the observation device antenna 5 may wirelessly receive a control signal from an external control device, for example, via the housing antenna 6. In addition, power may be supplied to the observation device antenna 5 from an external power supply device in a non-contact manner via the housing antenna 6.

The housing antenna 6 is an antenna installed in the housing 2. The housing antenna 6 includes an internal antenna 6a and an external antenna 6b. The internal antenna 6a is located inside the housing 2 and is wirelessly connected to the observation device antenna 5. The external antenna 6b is located outside the housing 2 and is wirelessly connected to an external device (not illustrated). The internal antenna 6a and the external antenna 6b are connected to each other.

The observation unit 1 according to the present example embodiment performs observation in a state where the observation device 4 is thermally separated from the housing 2. Therefore, even when the outside of the housing 2 is in a high-temperature environment, it is possible to suppress transfer of external heat to the observation device 4. Accordingly, the observation device 4 does not need to have resistance to external heat. That is, the observation unit 1 of the present example embodiment can perform observation using, for example, an observation device 4 having low heat resistance or an observation device 4 that is not heat resistant. In addition, an observation method using such an observation unit 1 can perform observation in a state where the observation device 4 is thermally separated from the housing 2.

The observation unit 1 of the present example embodiment as described above includes the housing 2, the pedestal 3, and the observation device 4. The inside of the housing 2 is vacuum. The pedestal 3 is accommodated in the housing 2 and fixed to the housing 2. The observation device 4 is accommodated in the housing 2 and supported by the pedestal 3. The pedestal 3 includes the pedestal magnet 3a. In addition, the observation device 4 includes the observation device magnet 4a installed so as to repel the pedestal magnet 3a. The observation device 4 is supported in a state of being separated from the pedestal 3.

In such an observation unit 1 of the present example embodiment, a gap S is provided between the pedestal 3 and the observation device 4, and the observation device 4 is supported in a non-contact manner with respect to the pedestal 3. Furthermore, the observation device 4 is accommodated in the housing 2 having a vacuum inside. Therefore, the observation device 4 is thermally separated from the housing 2. Accordingly, the observation unit 1 of the present example embodiment can suppress external heat from being transferred from the place supporting the observation device 4 to the observation device 4.

In addition, the observation unit 1 of the present example embodiment includes the observation device antenna 5 installed in the observation device 4 and the housing antenna 6 installed in the housing 2. Such an observation unit 1 of the present example embodiment can wirelessly connect an external device (not illustrated) and the observation device 4. Therefore, it is possible to receive observation data of the observation device 4 by the external device, to issue a command to the observation device 4 from the external device, or to supply power to the observation device 4 from the external device while suppressing transfer of external heat to the observation device 4.

In addition, in the observation unit 1 of the present example embodiment, the housing 2 has the observation window 2a in a portion thereof. The observation window 2a allows an observation target signal to be received by the observation device 4 to pass from the outside of the housing 2 to the inside of the housing 2.

Such an observation unit 1 of the present example embodiment allows the observation target signal from the outside to pass through to the inside of the housing 2 using the observation window 2a. Therefore, in the observation unit 1 of the present example embodiment, the observation device 4 can perform observation even if the remaining part of the housing 2 is formed of a material that does not pass the observation target signal.

In addition, in the observation method of the present example embodiment, the pedestal 3 and the observation device 4 are accommodated in the housing 2 having a vacuum inside. In addition, the observation method of the present example embodiment uses the repulsive force between the pedestal magnet 3a of the pedestal 3 fixed to the housing 2 and the observation device magnet 4a of the observation device 4 to support the observation device 4 in a state of being separated from the pedestal 3. In addition, in the observation method of the present example embodiment, observation is performed using the observation device 4 in a state of being separated from the pedestal 3.

In such an observation method of the present example embodiment, a gap S is provided between the pedestal 3 and the observation device 4, and the observation device 4 is supported in a non-contact manner with respect to the pedestal 3. Furthermore, the observation device 4 is accommodated in the housing 2 having a vacuum inside. Therefore, the observation device 4 is thermally separated from the housing 2. Accordingly, the observation method of the present example embodiment can suppress external heat from being transferred from the place supporting the observation device 4 to the observation device 4.

### Second Example Embodiment

Next, a second example embodiment of the present disclosure will be described. In the description of the present example embodiment, the description of parts similar to those of the first example embodiment will be omitted or simplified.

A traveling wave tube unit 10 of the present example embodiment includes a traveling wave tube 20 and the observation unit 1. The traveling wave tube unit 10 of the present example embodiment is a unit in which the state of the traveling wave tube 20 can be observed by the observation unit 1. That is, in the present example embodiment, the observation target of the observation unit 1 is the traveling wave tube 20.

The traveling wave tube 20 is a device that amplifies microwaves, and includes an electron gun 21, a periodic magnetic field device 22, a slow-wave circuit 23, and a collector 24. The electron gun 21 emits an electron beam toward the collector. The periodic magnetic field device 22 is disposed between the electron gun 21 and the collector 24, and focuses the electron beam. The slow-wave circuit 23 includes a helix circuit and the like arranged inside the periodic magnetic field device 22, and amplifies microwaves by converting kinetic energy of the electron beam into microwave energy. The collector 24 captures the electron beam that has passed through the periodic magnetic field device 22.

The periodic magnetic field device 22 includes a plurality of magnets 22a surrounding a passage 25 through which the electron beam passes in order to focus the electron beam. In addition, the periodic magnetic field device 22 includes ferromagnets 22b that holds the magnets 22a. The ferromagnets 22b is made of, for example, iron and surrounds the passage 25 through which the electron beam passes similarly to the magnets 22a. In the present example embodiment, a through hole 22c communicating with the passage 25 from the outside of the periodic magnetic field device 22 is provided in a portion of the ferromagnets 22b.

In such a traveling wave tube 20, the degree of vacuum and temperature are high inside the electron gun 21, the slow-wave circuit 23, and the collector 24 similarly to the passage 25 in order to facilitate propagation of electron beams. The periodic magnetic field device 22 also has a high temperature. The inside of the through hole 22c connected to the passage 25 also has a high degree of vacuum and a high temperature.

In the present example embodiment, the observation unit 1 is disposed outside the periodic magnetic field device 22 and is connected to the periodic magnetic field device 22. In the present example embodiment, the observation device 4 of the observation unit 1 includes a probe 4b and a reel 4c. In the present example embodiment, the observation device 4 performs observation by converting the observation target signal input via the probe 4b into an electrical signal.

The probe 4b can be formed of, for example, an optical fiber, and is formed to have a small diameter. The through hole 22c is formed to have a diameter through which the probe 4b can pass, but can be formed to have a small diameter similarly to the probe 4b. Therefore, the influence of the connection of the through hole 22c to the passage 25 on the microwave amplifying action can be extremely reduced. In addition, the diameter of the through hole 22c may be set to a size through which an electro-optic probe can pass so that an electro-optic probe can be used as the probe 4b.

The reel 4c winds and feeds the probe 4b. That is, the reel 4c can adjust the winding amount of the probe 4b. Note that another device may be installed instead of the reel 4c as long as it allows the probe 4b to be taken in and out of the passage 25.

The observation unit 1 also includes a tube 7 that is connected to the housing 2 and through which the probe 4b can be inserted. The tube 7 is connected to the housing 2, and the probe 4b can be inserted into the tube 7. The tube 7 is connected to the through hole 22c provided in the ferromagnets 22b. The inside of such a tube 7 also becomes vacuum similarly to the inside of the housing 2 and the passage 25 of the traveling wave tube 20.

In such a traveling wave tube unit 10 of the present example embodiment, the observation device 4 observes the passage 25, for example, in a period in which an electron beam is not emitted in the traveling wave tube 20. For example, the observation device 4 can perform observation of, for example, traces where an electron beam has struck in the passage 25 by image acquisition. Further, the probe 4b can be used to dispose a beam shape evaluation sheet in the passage 25 and collect the beam shape evaluation sheet from the passage 25. In addition, for example, by preventing the probe 4b from contacting the tube 7 or the inner wall of the through hole 22c, the passage 25 can be observed while an electron beam is being emitted.

The traveling wave tube unit 10 of the present example embodiment as described above includes the traveling wave tube 20 and the observation unit 1 whose observation target is the traveling wave tube 20. In such a traveling wave tube unit 10 of the present example embodiment, even when the temperature of the traveling wave tube 20 rises, observation by the observation unit 1 is possible without affecting the characteristics of the traveling wave tube 20. In addition, since the inside of the housing 2 is vacuum, it is possible to perform observation without affecting the vacuum of the traveling wave tube 20.

Since the traveling wave tube 20 can be observed in this manner, for example, it is possible to quickly respond to a malfunction of the traveling wave tube 20. In addition, the traveling wave tube unit 10 can also observe, for example, the shapes of peeled portions, scratches, burrs, and the like inside the traveling wave tube 20. In addition, since the traveling wave tube unit 10 can also observe the shape of the electron beam, the observation data can be used for the development of the traveling wave tube 20.

In the traveling wave tube unit 10 of the present example embodiment, the observation device 4 includes the probe 4b that can be sent out of the housing 2. According to such a traveling wave tube unit 10 of the present example embodiment, it is possible to directly observe the passage 25 using the probe 4b.

In the traveling wave tube unit 10 of the present example embodiment, the observation unit 1 includes the tube 7 that is connected to the housing 2 and through which the probe 4b can be inserted. Therefore, the probe 4b can be inserted into the traveling wave tube 20 through the tube 7. Furthermore, for example, by closing the tube 7 to interrupt it, it is possible to separate the traveling wave tube 20 and the observation unit 1 while maintaining the vacuum state in the housing 2 and the passage 25. Therefore, the traveling wave tube 20 can be a product in which the observation unit 1 is not provided. In addition, for example, the observation unit 1 can be reused by opening the interrupted portion of the tube 7.

In the traveling wave tube unit 10 of the present example embodiment, the observation device 4 includes the reel 4c capable of adjusting the winding amount of the probe 4b. According to such an observation device 4, the tip position of the probe 4b can be changed by adjusting the winding amount of the probe 4b on the reel 4c. This enables a wider area of the passage 25 to be observed.

In the traveling wave tube unit 10 of the present example embodiment, the traveling wave tube 20 includes the electron gun 21 that emits an electron beam, the periodic magnetic field device 22 that focuses the electron beam emitted from the electron gun 21, and the collector 24 that captures the electron beam that has passed through the periodic magnetic field device 22. In addition, the observation unit 1 is connected to the periodic magnetic field device 22 from the outside.

Such a traveling wave tube unit 10 of the present example embodiment does not need to accommodate the entire observation device 4 inside the passage 25 through which an electron beam passes. Therefore, it is possible to observe the traveling wave tube 20 without making a change that affects the characteristics of the traveling wave tube 20, for example, an increase in the size of the passage 25.

In the traveling wave tube unit 10 of the present example embodiment, the periodic magnetic field device 22 includes the magnets 22a and the ferromagnets 22b surrounding the passage 25 of the electron beam. In addition, the through hole 22c connected to the observation unit 1 is provided in the ferromagnets 22b.

The through hole 22c may have a diameter smaller than the signal wavelength in the traveling wave tube 20. Such a traveling wave tube unit 10 of the present example embodiment can suppress the through hole 22c from affecting the characteristics of the traveling wave tube 20.

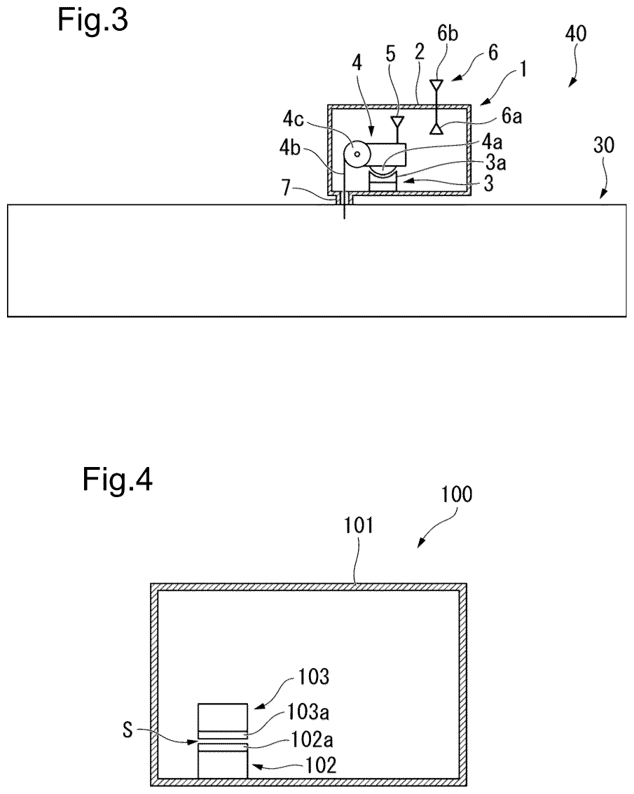

In the present example embodiment, a configuration in which the observation unit 1 is provided in the traveling wave tube 20 has been described. However, in the present disclosure, as illustrated in FIG. 3, instead of the traveling wave tube 20, the observation unit 1 may be connected to another microwave tube 30 such as a klystron or a magnetron to form a microwave tube unit 40. In addition, the present disclosure is also applicable to observation in a device having a region of high temperature and high degree of vacuum by appropriately selecting the location where the hole is provided.

### Third Example Embodiment

Next, a third example embodiment of the present disclosure will be described.

An observation unit 100 of the present example embodiment includes a housing 101, a pedestal 102, and an observation device 103. The inside of the housing 101 is vacuum. The pedestal 102 is accommodated in the housing 101 and fixed to the housing 101. The observation device 103 is accommodated in the housing 101 and supported by the pedestal 102. The pedestal 102 includes a first magnet 102a. The observation device 103 includes a second magnet 103a installed so as to repel the first magnet 102a. The observation device 103 is supported in a state of being separated from the pedestal 102.

In such an observation unit 100 of the present example embodiment, a gap S is provided between the pedestal 102 and the observation device 103, and the observation device 103 is supported in a non-contact manner with respect to the pedestal 102. Furthermore, the observation device 103 is accommodated in the housing 101 having a vacuum inside. Therefore, the observation device 103 is thermally separated from the housing 101. Accordingly, the observation unit 100 of the present example embodiment can suppress external heat from being transferred to the observation device 103 from the place supporting the observation device 103.

The vacuum heat-insulating container portion in JP 2023-154892 A has a reduced-pressure space surrounding the measurement device to suppress heat transfer from the outside to the measurement device through the reduced-pressure space. However, a cap or the like to which the measurement device is fixed is provided in a portion of the vacuum heat-insulating container. This cap is connected to the outside of the measurement-device-accommodating heat-insulating container without passing through the reduced-pressure space. Therefore, it is difficult for the measurement-device-accommodating heat-insulating container disclosed in JP 2023-154892 A to prevent external heat from being transferred to an observation device, for example, a measurement device, through a portion supporting it.

The present disclosure has been made in view of the above-described problems, and one of an object of the present disclosure is to prevent external heat from being transferred to an observation device from a portion supporting it.

The present disclosure can suppress external heat from being transferred from the place supporting the observation device to the observation device.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each embodiment can be appropriately combined with at least one of embodiments.

Some or all of the above-described example embodiments may be described as the following supplementary notes, but are not limited to the following supplementary notes.

### Supplementary Note 1

An observation unit including:
a housing having a vacuum inside;
a pedestal accommodated in the housing and fixed to the housing; and
an observation device accommodated in the housing and supported by the pedestal,
wherein the pedestal includes a first magnet, and
the observation device includes a second magnet installed so as to repel the first magnet, and is supported in a state of being separated from the pedestal.

### Supplementary Note 2

The observation unit according to Supplementary Note 1, further including a first antenna installed in the observation device, and
a second antenna installed in the housing.

### Supplementary Note 3

The observation unit according to Supplementary Note 1 or 2, wherein the housing has a signal passing portion that allows an observation target signal received by the observation device to pass from the outside of the housing to the inside of the housing.

### Supplementary Note 4

The observation unit according to any one of Supplementary Notes 1 to 3, wherein the observation device includes a probe that can be sent out of the housing.

### Supplementary Note 5

The observation unit according to Supplementary Note 4, further including a tube that is connected to the housing and through which the probe can be inserted.

### Supplementary Note 6

The observation unit according to Supplementary Note 4 or 5, wherein the observation device includes a reel capable of adjusting a winding amount of the probe.

### Supplementary Note 7

A traveling wave tube unit including:
a traveling wave tube; and
the observation unit according to any one of Supplementary Notes 1 to 6 for observing the traveling wave tube.

### Supplementary Note 8

The traveling wave tube unit according to Supplementary Note 7,
wherein the traveling wave tube includes
an electron gun that emits an electron beam,
a periodic magnetic field device that focuses the electron beam emitted from the electron gun, and
a collector that captures the electron beam that has passed through the periodic magnetic field device, and
the observation unit is externally connected to the periodic magnetic field device.

### Supplementary Note 9

The traveling wave tube unit according to Supplementary Note 8, wherein the periodic magnetic field device includes a magnet and a ferromagnet surrounding a passage of the electron beam, and
a through hole connected to the observation unit is provided in the ferromagnet.

### Supplementary Note 10

An observation method including:
accommodating a pedestal and an observation device inside a housing having a vacuum inside;
supporting the observation device in a state of being separated from the pedestal by using a repulsive force between a first magnet included in the pedestal fixed to the housing and a second magnet included in the observation device; and
performing observation using the observation device in a state of being separated from the pedestal.

### Supplementary Note 11

The observation method according to Supplementary Note 10, wherein a first antenna is installed in the observation device, and
a second antenna is installed in the housing.

### Supplementary Note 12

The observation method according to Supplementary Note 10 or 11, wherein a signal passing portion that allows an observation target signal received by the observation device to pass from the outside of the housing to the inside of the housing is provided in a portion of the housing.

### Supplementary Note 13

The observation method according to any one of Supplementary Notes 10 to 12, wherein the observation device includes a probe that can be sent out of the housing.

### Supplementary Note 14

The observation method according to Supplementary Note 13, wherein a tube through which the probe can be inserted is connected to the housing.

### Supplementary Note 15

The observation method according to Supplementary Note 13 or 14, wherein the observation device includes a reel capable of adjusting a winding amount of the probe.

### Supplementary Note 16

The observation method according to any one of Supplementary Notes 11 to 15, wherein a traveling wave tube is observed.

### Supplementary Note 17

The observation method according to Supplementary Note 16,
wherein the traveling wave tube includes
an electron gun that emits an electron beam,
a periodic magnetic field device that focuses the electron beam emitted from the electron gun, and
a collector that captures the electron beam that has passed through the periodic magnetic field device, and
the observation unit is externally connected to the periodic magnetic field device.

### Supplementary Note 18

The observation method according to Supplementary Note 17, wherein the periodic magnetic field device includes a magnet and a ferromagnet surrounding a passage of the electron beam, and
a through hole connected to the observation unit is provided in the ferromagnet.

### Supplementary Note 19

A microwave tube unit including:
a microwave tube; and
the observation unit according to any one of Supplementary Notes 1 to 6 for observing the microwave tube.

1. An observation unit comprising:
a housing having a vacuum inside;
a pedestal accommodated in the housing and fixed to the housing; and
an observation device accommodated in the housing and supported by the pedestal,
wherein the pedestal includes a first magnet, and
the observation device includes a second magnet installed so as to repel the first magnet, and is supported in a state of being separated from the pedestal.

2. The observation unit according to claim 1, further comprising a first antenna installed in the observation device, and
a second antenna installed in the housing.

3. The observation unit according to claim 1, wherein the housing has a signal passing portion that allows an observation target signal received by the observation device to pass from the outside of the housing to the inside of the housing.

4. The observation unit according to claim 1, wherein the observation device includes a probe that can be sent out of the housing.

5. The observation unit according to claim 4, further comprising a tube that is connected to the housing and through which the probe can be inserted.

6. The observation unit according to claim 4, wherein the observation device includes a reel capable of adjusting a winding amount of the probe.

7. A traveling wave tube unit comprising:
a traveling wave tube; and
the observation unit according to claim 1observing the traveling wave tube.

8. The traveling wave tube unit according to claim 7,
wherein the traveling wave tube includes
an electron gun that emits an electron beam,
a periodic magnetic field device that focuses the electron beam emitted from the electron gun, and
a collector that captures the electron beam that has passed through the periodic magnetic field device, and
the observation unit is externally connected to the periodic magnetic field device.

9. The traveling wave tube unit according to claim 8, wherein the periodic magnetic field device includes a magnet and a ferromagnet surrounding a passage of the electron beam, and
a through hole connected to the observation unit is provided in the ferromagnet.

10. A microwave tube unit comprising:
a microwave tube; and
the observation unit according to claim 1 observing the microwave tube.

11. An observation method comprising:
accommodating a pedestal and an observation device inside a housing having a vacuum inside;
supporting the observation device in a state of being separated from the pedestal by using a repulsive force between a first magnet included in the pedestal fixed to the housing and a second magnet included in the observation device; and
performing observation using the observation device in a state of being separated from the pedestal.

12. The observation method according to claim 11, wherein a first antenna is installed in the observation device, and
a second antenna is installed in the housing.

13. The observation method according to claim 11, wherein a signal passing portion that allows an observation target signal received by the observation device to pass from the outside of the housing to the inside of the housing is provided in a portion of the housing.

14. The observation method according to claim 11, wherein the observation device includes a probe that can be sent out of the housing.

15. The observation method according to claim 14, wherein a tube through which the probe can be inserted is connected to the housing.

16. The observation method according to claim 14, wherein the observation device includes a reel capable of adjusting a winding amount of the probe.

17. The observation method according to claim 12, wherein a traveling wave tube is observed.

18. The observation method according to claim 17,
wherein the traveling wave tube includes
an electron gun that emits an electron beam,
a periodic magnetic field device that focuses the electron beam emitted from the electron gun, and
a collector that captures the electron beam that has passed through the periodic magnetic field device, and
the observation unit is externally connected to the periodic magnetic field device.

19. The observation method according to claim 18, wherein the periodic magnetic field device includes a magnet and a ferromagnet surrounding a passage of the electron beam, and
a through hole connected to the observation unit is provided in the ferromagnet.
